(19) United States
(12) Patent Application Publication
(10) Pub. No.: US 2026/0056264 A1
(43) Pub. Date: Feb. 26, 2026

(54) Method And System For Diagnosing Voltage Transformers

(71) Applicant: ELECTRICITE DE FRANCE, PARIS (FR)

(72) Inventors: Bernard Paya, Melun (FR); Alain Jeanmaire, Paron (FR)

(73) Assignee: ELECTRICITE DE FRANCE, Paris (FR)

(21) Appl. No.: 19/104,931

(22) PCT Filed: Aug. 16, 2023
(86) PCT No.: PCT/FR2023/051272

§ 371 Date: Feb. 19, 2025

(30) Foreign Application Priority Data
Aug. 23, 2022 (FR) FR2208454

(51) Int. Cl. G01R 31/62; G01R 19/02

(52) U.S. Cl. CPC G01R 31/62; G01R 19/02

(57) ABSTRACT

The invention relates to a method for monitoring voltage transformers (TTa) that are each connected to one of the phases (Pa, Pb, Pc) of one and the same three-phase high-voltage line, the method comprising the following steps: —on the basis of a measurement of a secondary voltage of each of the voltage transformers in a time window, determining a peak homopolar voltage (VHM) and three RMS voltages (Veff(Va), Veff(Vb), Veff(Vb)) each corresponding to the RMS voltage of the secondary voltage (Va, Vb, Vc) of one of the voltage transformers; —determining a reference RMS voltage; —when the peak homopolar voltage exceeds a first threshold; ∘determining a difference between the reference RMS voltage and one of the three determined RMS voltages: ∘detecting an error when the difference is greater than a second threshold.

### TECHNICAL FIELD

The field of the invention is that of electrical equipment equipping an electricity transmission network and more specifically the field of voltage transformers installed in high-voltage substations. The invention relates to the diagnosing of faults in such voltage transformers.

### PRIOR ART

Voltage transformers are generally installed in high-voltage substations in order to reduce a phase-to-earth voltage to be measured at a level compatible with measurement apparatuses, which are generally low-voltage. In particular, for one and the same three-phase high-voltage line forming an outgoing or incoming line of a substation, one encounters three voltage transformers each connected to one of the phases of the three-phase high-voltage line.

In particular, one may encounter transformers based on capacitive divider technology, such as capacitive voltage transformers for example meeting the IEC 61869-5 standard or else Low Power Voltage Transformers (LPVT) in a capacitive divider or resistive-capacitive divider assembly, whether they are passive (for example according to the IEC 61869-11 standard) or electronic (for example according to the next standard IEC 61869-7).

One may also encounter transformers based on inductive divider technology, such as for example those meeting the IEC 61869-3 standard. Transformers based on capacitive divider technology are however generally preferred to transformers based on inductive divider technology due to their lower cost.

The operating principle of a capacitive voltage transformer TCT is illustrated by FIG. 1. The transformation of the TCT is done in two steps: first by a capacitive voltage divider 1 which ensures the high-voltage U_{HT} (also known by the term primary voltage, at the transformer input)/medium-voltage U_{MT} reduction, then by an inductive transformer 2 which compensates the reactive current and the medium-voltage U_{MT}/low-voltage U_{BT} (also referred to by the term secondary voltage, at the transformer output) reduction. The capacitive divider 1 is composed of a stack of series-connected unit capacitors, of substantially equal capacitances, which are grouped into two blocks: a high-voltage block C1 numbering N1 capacitors and a medium-voltage block C2 numbering N2 capacitors. The overall capacitance of each block then has a value of

$${C}_{i} = \frac{C}{{N}_{i}}$$

with i=(1, 4) and the transformation ratio K_{c} of the capacitive divider 1 is expressed as

$${K}_{C} = \frac{{U}_{HT}}{{U}_{MT}} = \frac{{C}_{1} + {C}_{2}}{{C}_{1}} .$$

The unit capacitors being substantially identical, the primary voltage U_{HT} is shared in a balanced manner between all the capacitors of the blocks C1 and C2.

The most frequent mode of degradation over time of the transformer TCT is that of sparking between the two electrodes of a capacitor causing it to short-circuit. This results in an increase in the capacitance of the block containing the defective capacitor by reduction of the number Nᵢ of active capacitors, which leads to a drift in the transformer ratio K_{C} of the transformer TCT and, consequently, its accuracy. A malfunction in the block C1 manifests as a reduction in the transformer ratio K_{C} and therefore as an increase in the voltage U_{MT} measured through the medium-voltage/low-voltage stage. Reciprocally, a malfunction in the block C2 manifests as an increase in the transformer ratio K_{C} and therefore as a reduction in the voltage U_{MT} measured through the medium-voltage/low-voltage stage. Moreover, the loss of a capacitor ensures that the primary voltage is redistributed between the healthy capacitors. The voltage across the terminals of each healthy capacitor is then higher, each healthy capacitor being overloaded.

This mode of degradation gives rise to a drift in accuracy of the TCT which should be closely monitored in order to be able to perform scheduled repairs to replace the malfunctioning TCT, during maintenance for example, before this drift becomes too large.

It is known that errors in the control or protection of an electrical network may be the result of a poor evaluation of the real voltage of the network. However in this case, a drift in a TCT can be interpreted as an imbalance of the network. This can therefore result in incorrect commands being made in an attempt to correct this imbalance.

In particular, errors in energy metering may manifest either as an overvaluation, or as an undervaluation of the energy travelling through a high-voltage substation, according to the location of the malfunctioning capacitor that is modifying the transformation ratio K_{C} of the capacitive divider. Metering standards require the operator to use voltage transformers of 0.5 class (0.5% error on the signal amplitude) or more accurate ones. The drifts in accuracy observed on malfunctioning TCTs can place them outside the requisite accuracy class for metering operations, and consequently render them unfit for this use.

It has also been found that the drift in accuracy is accompanied by an overloading of the healthy capacitors which makes them more fragile. Due to the runaway effect, the degradation of the TCT can be speeded up, which can end in the destruction of the TCT, sometimes by explosion, and collaterally that of other equipment items present in the substation. It is therefore important to be able to quickly detect the beginnings of a drift before the situation can deteriorate.

The solution imposed by the French electricity transmission network operator (Gestionnaire du Réseau de Transport d′électricité or GRT) consists in measuring the homopolar secondary voltage, i.e. the instantaneous sum of the secondary voltages of the TCT each associated with one of the phases of one and the same three-phase high-voltage line. Above a threshold set by the GRT, the user of the transmission network has the obligation to disconnect from the transmission network, for the time it takes to replace the malfunctioning TCT. This is because the GRT deems that a drift above this threshold can cause a rapid degradation of the TCT which is harmful to the stability of the electrical network to which it is connected.

Waiting until the alert threshold set by the GRT is reached to replace the malfunctioning TCT compels the producing user to disconnect from the network during this unscheduled maintenance to allow the GRT to guarantee the stability of the network. The time period needed by the producing user to re-establish its ability to supply electrical energy to the transmission network in accordance with GRT regulations is in the order of 24 hours, conditional on the availability of another TCT. During this time period, the GRT must rely on other unscheduled production units in order to ensure the balance between electricity supply and demand. Meanwhile the consuming user, which is forced to disconnect, no longer has the electrical energy needed for its operations.

An analysis of the operation of TCTs shows that it is possible to identify smaller drifts which avoid this alert level being reached. It is then possible to continue to exploit the malfunctioning TCT without contravening the GRT regulations. The replacement of the TCT can thus be scheduled during a maintenance phase following the detection of this small drift.

A solution of ex situ diagnosis consists in disassembling the TCTs associated with one and the same outgoing or incoming line to test them in the laboratory. However, this solution is unacceptable for the user since it renders the outgoing or incoming line in question unusable over a long period.

Another solution, described for example in the international applications WO 2014/162020 A1 and WO 2014/162021 A1, has been developed by the Spanish company Arteche in order to perform an in situ diagnosis of the TCTs of a substation possessing several three-phase outgoing lines. This solution is based on the comparison of the secondary signals delivered by the TCTs associated with one and the same phase of the different three-phase outgoing lines, these secondary signals being meant to correspond to one and the same primary voltage signal. The drift of one TCT with respect to the others manifests as a deviation in the secondary signal which is then interpreted by a control terminal of the assembly. This deviation then makes it possible to identify the TCT or TCTs that are drifting and the origin of their drift. To provide a reliable diagnosis, it is necessary to possess at least three three-phase outgoing lines equipped with TCTs or one outgoing line equipped with an inductive voltage transformer which then serves as reference.

This solution of the Spanish company Arteche is not suitable for substations possessing only a single three-phase outgoing or incoming line (power evacuation substations of production units, delivery substations of customers supplied with high-voltage power, etc.). In such a scenario, it is not possible to possess a reference voltage enabling comparison with the TCT to be diagnosed. Moreover, if for small substations possessing only two outgoing lines (or incoming lines) this solution makes it possible to detect whether or not there is a problem, it still does not make it possible to identify the malfunctioning TCT.

It will be noted that LPVT transformers, which are based on the capacitive structure or resistive-capacitive divider structure and possess only a single high-voltage/medium-voltage transformation stage, can be subject to the same types of malfunction by the sparking of unit capacitors.

A drift in the accuracy of transformers based on inductive divider technology is also liable to occur, as a consequence of a fault in the insulation of the wires of the transformer windings then short-circuiting several turns of a winding. The measured value of the secondary voltage can then be higher or lower than the actual voltage according to whether the fault respectively appears on the primary winding or on the secondary winding/one of the secondary windings. Moreover, a high induction current flows through the short-circuited windings, liable to cause a greater degree of heating than the transformer can withstand. Electrical sparks, the explosion of the device or a fire breakout in the dielectric materials such as oils or resins can ensue.

### SUMMARY OF THE INVENTION

The aim of the invention is to make provision for a solution for the in situ diagnosis of voltage transformers equipping a high-voltage substation which can make it possible to dispense with at least one of the drawbacks mentioned.

To do this, the invention makes provision for a method for monitoring voltage transformers each connected to one of the phases of one and the same three-phase high-voltage line, comprising the following steps:
based on a measurement of a secondary voltage of each of the voltage transformers over a time window, determining a peak homopolar voltage of three root-mean-square voltages each corresponding to the root-mean-square voltage of the secondary voltage of one of the voltage transformers;
determining a reference root-mean-square voltage based on the three determined root-mean-square voltages;
when the peak homopolar voltage exceeds a first threshold:
   determining a deviation between the reference root-mean-square voltage and the one of the three determined root-mean-square voltages that is the furthest from the reference root-mean-square voltage;
   detecting an error of the voltage transformer corresponding to the one of the three determined root-mean-square voltages that is the furthest from the reference root-mean-square voltage when said deviation is greater than a second threshold. Certain preferred but non-limiting aspects of this method are as follows:
the determining of the reference root-mean-square voltage comprises the determining of the two root-mean-square voltages having the smallest relative deviation from among the three determined root-mean-square voltages and the computing of the average of said two root-mean-square voltages;
the first threshold is a fraction of the reference root-mean-square voltage;
the second threshold is identical to the first threshold;
the voltage transformers each have an integrated capacitive voltage divider or a resistive-capacitive voltage divider comprising a high-voltage stage and a medium- or low-voltage stage and the error is attributed to the high-voltage stage, or the medium- or low-voltage stage respectively, of the voltage transformer corresponding to the one of the three determined root-mean-square voltages that is the furthest from the reference root-mean-square voltage, when the one of the three determined root-mean-square voltages that is the furthest from the reference root-mean-square voltage is greater, or respectively less than, the reference root-mean-square voltage;
the voltage transformers are inductive transformers each comprising a primary winding and a secondary winding and in which the error is attributed to the primary winding, or the secondary winding respectively, of the voltage transformer corresponding to the one of the three determined root-mean-square voltages that is the furthest from the reference root-mean-square voltage when the one of the three determined root-mean-square voltages that is the furthest from the reference root-mean-square voltage is greater than, or respectively less than, the reference root-mean-square voltage;
it comprises the reiterating of said steps and the generating of an alert when an error in one of the voltage transformers is detected during several consecutive iterations of said steps;
the measuring of the secondary voltage of each of the voltage transformers over the time window corresponds to a set of successive digital samples each associated with an adequate quality level;
the determining of the three root-mean-square voltages comprises the detecting of the zero crossings of the secondary voltage measured for each of the voltage transformers over the time window.

### BRIEF DESCRIPTION OF THE DRAWINGS

Other aspects, aims, advantages and features of the invention will become more apparent on reading the following detailed description of preferred forms of embodiment thereof, given by way of non-limiting example, and with reference to the appended drawings on which:

FIG. 1, already discussed previously, is a diagram of a capacitive voltage transformer;

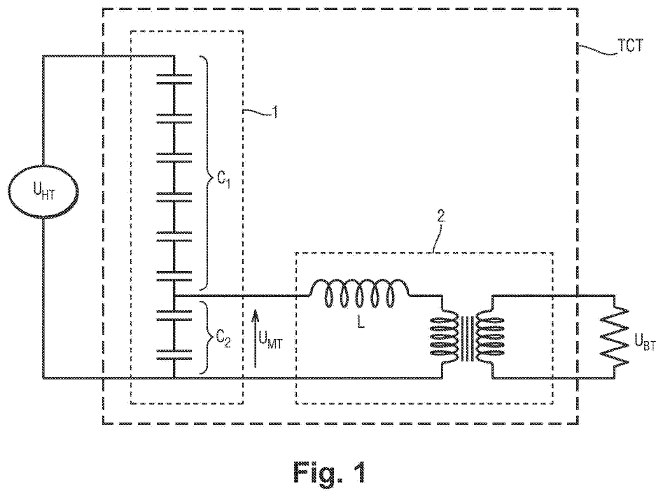

FIG. 2 is a diagram of a diagnosing system in accordance with one possible implementation of the invention;

FIG. 3 is a process chart illustrating one possible embodiment of the method according to the invention.

### DETAILED SUMMARY OF PARTICULAR EMBODIMENTS

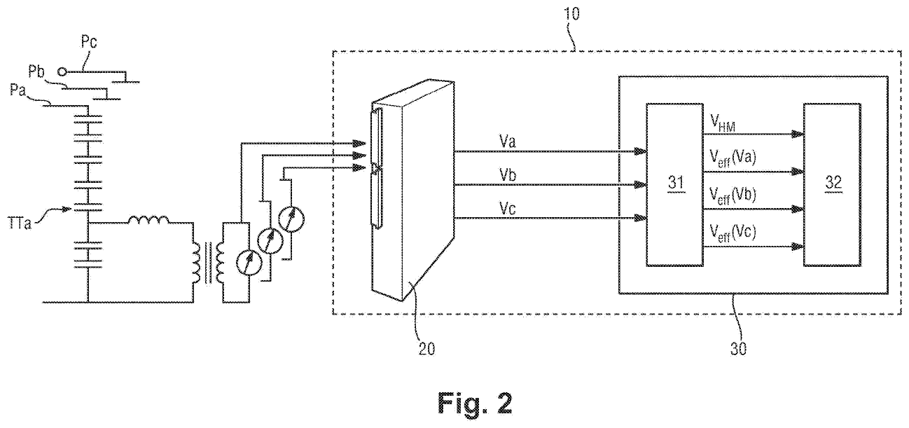

With reference to FIG. 2, the invention relates to a method for monitoring voltage transformers each connected to one of the phases Pa, Pb, Pc of one and the same three-phase high-voltage line forming an outgoing or incoming line of a substation. For the sake of legibility, a single voltage transformer TTa is shown on FIG. 2, in this case a capacitive voltage transformer associated with the phase Pa. The invention is not limited to this type of transformer and also extends to LPVT transformers in capacitive divider or resistive-capacitive divider configuration or else to inductive voltage transformers.

Still with reference to FIG. 2, the method according to the invention is implemented by a system 10 for diagnosing faults in voltage transformers. This system 10 comprises a monitoring apparatus 30 and, optionally when the voltage transformers deliver an analog signal, an analog-to-digital converter 20. Voltage transformers delivering a digital signal have their own integrated analog-to-digital converter to which the monitoring apparatus 30 is then coupled. Such an integrated analog-to-digital converter for example takes the form of a hub of MU (Merging Unit) type able to deliver to the monitoring apparatus 30 a stream of data in accordance with the IEC 61850 September 2 protocol. In the remainder of the text the example will be used of transformers with analog output, without the invention being limited to this type of transformer.

The analog-to-digital converter 20 is coupled, on the one hand, to a secondary of each of the voltage transformers and, on the other hand, to the monitoring apparatus 30. The analog-to-digital converter 20 is configured to convert into sampled values the analog signals from voltage measurement transformers VTa equipping the secondary of each of the voltage transformers and to supply the values thus sampled to the monitoring apparatus 30.

The monitoring apparatus 30 comprises a module 31 for computing characteristic voltages and a module 32 for interpreting the state of the voltage transformers, the functions of which will be described hereinafter. The monitoring apparatus 30 typically takes the form of a microcontroller in which is implemented a software program for processing data from the analog-to-digital converter 20 to establish a diagnosis.

In an exemplary embodiment, the voltage transformers TTa, each associated with one of the phases Pa, Pb, Pc of the three-phase line, are connected by their secondary output to three entries of the analog-to-digital converter 20 (typically a SAMU for Stand-Alone Merging Unit). The signals of the three inputs are sampled synchronously by the analog-to-digital converter 20. The sampling frequency can be adapted to the desired measurement accuracy, in particular if one wishes to take into account the harmonics in a fine-grained manner. Shannon's theorem specifies that the minimum sampling frequency is the double of the frequency that one wishes to observe. The frequencies 4 000 and 4 800 Hz can in particular be used, which are standardized for the IEC 61850 September 2 protocol and thus make it possible to explore up to harmonic 40 of the 50 Hz or 60 Hz networks.

The samples Va, Vb and Vc resulting from the digitization of the secondary voltages of the voltage transformers can be conditioned so as to be able to identify the time of sampling (for example in the form of a sample number with respect to a time reference, binary-encoded). A level of quality can be associated with each of these samples (Va, Vb and Vc.

Thus conditioned, these samples are sent in the form of data streams over a transmission line of computerized type. This data stream can be in accordance with the IEC 61850 September 2 standard relating to the transmission of sampled values and be sent over an Ethernet field bus.

The use of a stand-alone hub of SAMU type in accordance with the IEC 61869-13 standard offers the advantages listed below.

First of all, the input voltages of the voltage measurement channels are compatible with the output voltages of the voltage transformer in accordance with the IEC 61869-5 standard, a standard currently used in substations.

Next, the input impedance of the voltage measurement channels is high enough (typically in the order of the megohm) for the power drawn by the voltage transformer to be negligible compared to the accuracy power of said voltage transformer. The voltage transformer then operates within its accuracy class as defined in § 5.6 of the IEC 61869-5 standard and the connection of the SAMU does not make the accuracy of the measurement reducer drift.

Moreover, the accuracy of the analog-to-digital conversion is identified by an accuracy class as defined in § 5.6.1302 of the IEC 61869-13 standard. This makes it possible to guarantee that the conversion does not cause any excessive drift in accuracy in relation to that which one wishes to observe. The typical accuracy classes are the classes 0.5 and 0.2 respectively corresponding to amplitude errors of ±0.5% and ±0.2% and to phase shift errors of ±20′ and ±10′. It is of course possible to use more accurate classes than the 0.2 class.

Finally, the insulation of the inputs of the measurement transformers of the SAMU must comply with the requirements specified in § 5.3.1301 of the IEC 61869-13 standard. Hence, the inputs will support the secondary voltages resulting from the waves used to evaluate the insulation levels required by the IEC 61869-5 standard concerning TCTs. The conditions for operating in complete safety are thus observed.

The monitoring unit 30 is connected to the transmission line of the data stream so as to receive the data from the analog-to-digital converter 20. The monitoring unit 30 is configured to decode the frames of the digital signals and reconstitute the signals corresponding to the secondary voltage measurements of the voltage transformers Va, Vb and Vc in the form of tables of values, each row of the table corresponding to a given time of sampling.

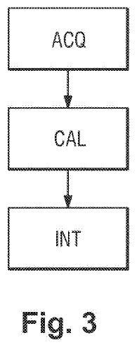

With reference to FIG. 3, the method according to the invention comprises a step ACQ of acquiring, by the module 31 for computing the characteristic voltages of the monitoring unit 30, a measurement Va, Vb, Vc of a secondary voltage of each of the voltage transformers over a time window.

In a possible embodiment, over an analysis cycle of predetermined duration (10 seconds for example), the monitoring unit 30 selects a subset of data for which it has obtained all the error-free samples, i.e. samples having an adequate level of quality over the time window (2 seconds of samples for example, that is approximately 100 periods of the 50 Hz signal). The duration of the time window is expressive of the phenomena that one is seeking to observe. It makes it possible to eliminate rapid fluctuations (duration of less than the mains period). It also leaves enough time for the processing of the data within one analysis cycle.

The method according to the invention then comprises a step CAL of determining, by the module 31 for computing characteristic voltages of the monitoring unit, a peak homopolar voltage V_{HM} and three root-mean-square voltages V_{eff}(Va), V_{eff}(Vb), V_{eff}(Vc) each corresponding to the root-mean-square voltage of the secondary voltage Va, Vb, Vc of one of the voltage transformers.

In a possible embodiment, a digital filtering of the signals by a low-pass filter (having for example a cut-off frequency of 100 Hz) is done prior to the step CAL to limit the digital noise resulting from the analog-to-digital conversion.

During the step CAL, the determining of the peak homopolar voltage V_{HM} comprises the computing of the instantaneous homopolar voltage Vh, which is the sum of the three secondary voltages Va, Vb and Vc, and the determining of its peak value over the time window.

The step CAL moreover comprises the computing of the frequency of the network by searching for zero crossings of the secondary voltages. In a possible embodiment, one or more periods (four for example) of the samples at each end of the subset are not taken into consideration, which makes it possible to eliminate errors related to the edge effects of the digital filter. The determining of the root-mean-square voltages V_{eff}(Va), V_{eff}(Vb), V_{eff}(Vc) can be done by integration over the largest integer number of periods NT in the subset of data, after any elimination of the periods at the ends, according to

$${V}_{eff} ( V x ) = \sqrt{\frac{1}{{N}_{T} T} {\int }_{0}^{{N}_{T} T} {V x ( t )}^{2} dt} with x = ( a , b , c )$$

and T the duration of one period.

The method according to the invention then comprises a step INT, implemented by the module 32 for interpreting the state of the voltage transformers, of detecting any error of one of the voltage transformers.

This step INT comprises the determining of a reference root-mean-square voltage V_{eff_M} based on the three determined root-mean-square voltages V_{eff}(Va), V_{eff}(Vb), V_{eff}(Vc). In a possible embodiment, the reference root-mean-square voltage V_{eff_M} corresponds to the average of the three determined root-mean-square voltages V_{eff}(Va), V_{eff}(Vb), V_{eff}(Vc). In a preferred embodiment making it possible to increase the sensitivity of the diagnosis, the determining of the reference root-mean-square voltage V_{eff_M} comprises the determining of the two root-mean-square voltages having the smallest relative deviation (as an absolute value) from among the three determined root-mean-square voltages (i.e. the two closest root-mean-square voltages) and the computing of the average of said two root-mean-square voltages.

In a possible embodiment, the step INT comprises the comparing of each of the three determined root-mean-square voltages with a threshold value (for example corresponding to a cutoff threshold, such as 10% of a theoretical primary voltage of the network) and the determining of the presence of the network voltage on the high-voltage electrical line when the root-mean-square values of the three phase-to-neutral voltages are all above the threshold value. In the absence of any network voltage, the step INT concludes that there is no error.

In the presence of a network voltage, the step INT comprises the comparing of the peak homopolar voltage V_{HM} with a first threshold. This first threshold can be set with respect to the reference root-mean-square voltage V_{eff_M}, for example 3% of the reference root-mean-square voltage V_{eff_M}.

If the peak homopolar voltage V_{HM} is less than the first threshold, the step INT concludes that there is no error. In the opposite case, the step INT concludes that there is an error. The value of this first threshold is preferably chosen well below the alert threshold set by the GRT but high enough to disregard the natural fluctuations of the electrical network. In the case of a capacitive transformer or LPVT, this first threshold remains expressive of an incipient malfunction of the transformer since it makes it possible to detect the sparking of a single unit capacitor of the column of the capacitive divider.

The identification of which of the three voltage transformers is affected by this error is performed as follows.

When the peak homopolar voltage exceeds the first threshold, the step INT comprises the determining of a deviation between the reference root-mean-square voltage V_{eff_M} and the one of the three determined root-mean-square voltages that is the furthest from the reference root-mean-square voltage. In the preferred embodiment described previously in which the reference root-mean-square voltage corresponds to the average of the two closest root-mean-square voltages values, the one of the three determined root-mean-square voltages that is the furthest from the reference root-mean-square voltage is therefore the root-mean-square voltage that is not used in the computing of this average.

This deviation is compared with a second threshold, which can be identical to the first threshold, for example 3% of the reference root-mean-square voltage V_{eff_M}.

If the deviation is less than the second threshold, the step INT concludes that the error cannot be attributed to one of the three voltage transformers in particular. The error can then be identified as being a phase angle error.

If the deviation is above the second threshold, the step INT detects an error of the voltage transformer corresponding to the one of the three determined root-mean-square voltages that is the furthest from the reference root-mean-square voltage V_{eff_M}.

When the voltage transformers each have an integrated capacitive voltage divider or a resistive-capacitive voltage divider comprising a high-voltage stage and a medium- or low-voltage stage, the step INT may comprise the attribution of the error to the high-voltage stage, or to the medium- or low-voltage stage respectively, of the voltage transformer corresponding to the one of the three determined root-mean-square voltages that is the furthest from the reference root-mean-square voltage when the one of the three determined root-mean-square voltages that is the furthest from the reference root-mean-square voltage is greater, or respectively less than the reference root-mean-square voltage (the transformation ratio K_{C} is then less, or respectively greater than, the theoretical transformation ratio).

When the voltage transformers are inductive transformers comprising a primary winding and one or more secondary windings, the step INT may comprise the attribution of the error to the primary winding, or respectively to the secondary winding connected to the fault diagnosing system 10, of the voltage transformer corresponding to the one of the three determined root-mean-square voltages that is the furthest from the reference root-mean-square voltage when the one of the three determined root-mean-square voltages that is the furthest from the reference root-mean-square voltage is greater, or respectively less than the reference root-mean-square voltage.

It will be noted that certain inductive transformers possess two secondary windings: one is used for measurement or control, the other is used for protection. In this case, a fault of the primary winding is seen on both the secondary outputs while a fault of a secondary winding is only seen on the corresponding secondary output.

In one possible embodiment, the steps of the method are reiterated and an alert is generated when an error of one of the voltage transformers is detected during several consecutive iterations of said steps (for example 6 iterations). The error is thus considered as being confirmed. In the opposite case, the step INT may conclude that the detected error is the result of a transient phenomenon of the electrical network and not from a malfunction of one of the voltage transformers.

The different voltage values and the different results of the diagnosis performed by the system 10 can be stored in log files for later, ex situ use.

We have previously seen that the digital values may be digitally filtered (for example by a low-pass filter of a cutoff frequency of 100 Hz). However this filtering incurs a natural reduction in the voltage values. In order to correct this effect, a correction ratio of 1/a can be applied to the stored voltage values in the log files where a corresponds to the peak value at the output of the digital filter of a sine wave signal at the frequency of the network (determined by the zero crossing method) having, before processing by the digital filter, a unit peak value.

It will be remembered that the invention has as originality the fact that the diagnosis is only based on the signals of the three phases of the three-phase network, which are assumed to be balanced. It does not make use of any external reference signal habitually used to evaluate the accuracy of the sensor to be tested by the comparison of two time-based signals (method used in the IEC 61869-5 § 7.2.6 standard to perform the laboratory testing of the accuracy of a capacitive voltage transformer).

Also, by contrast with the in situ solution developed by the company Arteche, according to the invention the comparison of the amplitudes of the voltages measured is not done between the outgoing lines of one and the same phase but between the three phases of a single three-phase outgoing (or incoming) line. Moreover, the solution of the company Arteche compares the values of the voltages of several outgoing lines and of one and the same phase at each instant in time of the voltage wave, i.e. at each synchronized sample. In the absence of drift, all the values must be identical, within the accuracy of the diagnosis system. The solution forming the subject of the invention compares the three signals of the three phases which are by nature out of phase by approximately 120° with respect to one another; the direct comparison of the time-based signals does not make it possible to perform the diagnosis simply. The processing of the information described in the invention is required to arrive at the desired result.

The installation of the solution of the company Arteche moreover requires the de-energizing of the substation. The measurement sensors are installed in the substation at the foot of the tested voltage transformers and are connected at a secondary connection box. For each tested voltage transformer, it is necessary to enter the substation again to move the measurement sensor from one voltage transformer to the other. The installation of the solution forming the subject of the invention can be done in the control facility of the operator at the place where the secondary signals of the three phases of the outgoing line or of the incoming line arrive. The connection can thus be embodied in conditions of increased safety due to the absence of high voltages in this facility.

The diagnosis according to the invention can moreover be insensitive to the slow fluctuations of the network (in relation to the period of the network): voltage fluctuations, frequency fluctuations. Slow voltage fluctuations are generally identical for the three phases of the network and the drift criteria used in the invention are based on a relative deviation of the voltages from one another. The slow fluctuations in frequency are measured by the zero crossing method and the value obtained is taken into account in the evaluation of the root-mean-square values of the voltages. The rapid and transient fluctuations of the network can also be eliminated since, although they are detected as errors, they do not generate any alerts due to their fleeting nature. Only errors of a permanent nature are retained.

The invention makes it possible to identify the malfunctioning transformer and the origins of its malfunction well before the threshold required by the GRT is reached. It is thus possible to continue to temporarily use the malfunctioning transformer and be able to schedule its replacement during routine maintenance of the station. The sensitivity of the diagnosis also makes it possible to disregard normal fluctuations of the electrical network to only trigger alerts when the fault of the transformer is confirmed.

The invention proves particularly beneficial for substations possessing only a single outgoing line (evacuation substation of the producer) or a single incoming line (customery delivery substation) since the other solutions present on the market cannot be applied to these types of substations.

The invention is however not limited to such an architecture and can also be implemented in order to monitor several outgoing or incoming lines within one and the same substation. Each three-phase outgoing or incoming line is associated with its three-phase analog-to-digital converter. To allow comparisons of the different outgoing lines, a signal is sent to the different analog-to-digital converters to ensure the synchronization of the sampling of the measurement channels between the analog-to-digital converters. The streams of digital data generated are sent over one and the same transmission line or over several transmission lines to a single monitoring unit. The diagnosis can then be refined by performing an intercomparison of the different three-phase outgoing or incoming lines in addition to the diagnosis described previously. The use of SAMUs described in the preferred embodiment makes it possible to embody this variant simply, the different SAMUs injecting their data stream into the Process Bus network to which the monitoring unit is also connected. Different modes of synchronization are proposed by the IEC 61869-13 standard; the one preferred by the standard uses the Process Bus network applying the PTP protocol. This avoids having to install an additional network dedicated to the synchronization signal.

Note that the invention is also applicable to the digital substations already equipped with a Process Bus network distributing the “Sampled Values” data streams integrated into LPVT digital-output transformers or stand-alone SAMU hubs connected to capacitive voltage transformers or analog-output LPVTs. In such a scenario, it suffices to connect the monitoring unit to this same network to be able to perform the diagnosis forming the subject of the invention. This variant is also applicable to low-power measurement reducers with digital output, combining the measurement of the phase-to-neutral voltage (LPVT) and the measurement of the phase current (LPCT for Low Power Current Transformer).

The invention is not limited to the method previously described but also extends to a computer program comprising instructions which, when the program is executed by a computer, lead it to implement this method, to a monitoring apparatus comprising a processor configured to implement this method, as well as to a diagnosing system comprising an analog-to-digital converter and such a monitoring apparatus, the analog-to-digital converter being coupled, on the one hand, to a secondary of each of the voltage transformers and, on the other hand, to said monitoring apparatus. The invention also relates to a high-voltage substation equipped with such a diagnosing system or with such a monitoring apparatus.

1. A method for monitoring voltage transformers each connected to one of the phases of one and the same three-phase high-voltage line, comprising the following steps:
based on a measurement of a secondary voltage of each of the voltage transformers over a time window, determining a peak homopolar voltage and three root-mean-square voltages each corresponding to a root-mean-square voltage of the secondary voltage of one of the voltage transformers;
determining a reference root-mean-square voltage based on the three determined root-mean-square voltages;
when the peak homopolar voltage exceeds a first threshold:
determining a deviation between the reference root-mean-square voltage and the one of the three determined root-mean-square voltages that is the furthest from the reference root-mean-square voltage;
detecting an error of the voltage transformer corresponding to the one of the three determined root-mean-square voltages that is the furthest from the reference root-mean-square voltage when said deviation is greater than a second threshold.

2. The method as claimed in claim 1, wherein determining of the reference root-mean-square voltage comprises determining the two determined root-mean-square voltages having the smallest relative deviation from among the three determined root-mean-square voltages and the computing of the average of said two determined root-mean-square voltages.

3. The method as claimed in claim 1, wherein the first threshold is a fraction of the reference root-mean-square voltage.

4. The method as claimed in claim 1, wherein the second threshold is identical to the first threshold.

5. The method as claimed in claim 1, wherein the voltage transformers each have an integrated capacitive voltage divider or a resistive-capacitive voltage divider comprising a high-voltage stage and a medium- or low-voltage stage and wherein the error is attributed to the high-voltage stage, or the medium- or low-voltage stage respectively, of the voltage transformer corresponding to the one of the three determined root-mean-square voltages that is the furthest from the reference root-mean-square voltage, when the one of the three determined root-mean-square voltages that is the furthest from the reference root-mean-square voltage is greater, or respectively less than, the reference root-mean-square voltage.

6. The method as claimed in claim 1, wherein the voltage transformers are inductive transformers each comprising a primary winding and a secondary winding and wherein the error is attributed to the primary winding, or the secondary winding respectively, of the voltage transformer corresponding to the one of the three determined root-mean-square voltages that is the furthest from the reference root-mean-square voltage when the one of the three determined root-mean-square voltages that is the furthest from the reference root-mean-square voltage is greater than, or respectively less than, the reference root-mean-square voltage.

7. The method as claimed in claim 1, comprising the reiterating of said steps and the generating of an alert when an error in one of the voltage transformers is detected during several consecutive iterations of said steps.

8. The method as claimed in claim 1, wherein the measurement of the secondary voltage of each of the voltage transformers over the time window corresponds to a set of successive digital samples each associated with an adequate quality level.

9. The method as claimed in claim 1, wherein determining of the three root-mean-square voltages comprises detecting zero crossings of the measurement of the secondary voltage of each of the voltage transformers over the time window.

10. A non-transitory computer-readable product storing a program having instructions which, when the program is executed by a computer, cause the computer to implement the method as claimed in claim 1.

11. An apparatus for monitoring voltage transformers each connected to one of the phases of one and the same three-phase high-voltage line, comprising a processor configured to implement the steps of the method as claimed in claim 1.

12. A system for diagnosing faults in voltage transformers each connected to one of the phases of one and the same three-phase high-voltage line, comprising an analog-to-digital converter and a monitoring apparatus as claimed in claim 11, the analog-to-digital converter being coupled, on the one hand, to a secondary of each of the voltage transformers and, on the other hand, to said monitoring apparatus.

13. A high-voltage substation comprising voltage transformers each connected to one of the phases of one and the same three-phase high-voltage line and a diagnosing system as claimed in claim 12.

14. A high-voltage substation comprising voltage transformers each connected to one of the phases of one and the same three-phase high-voltage line and a monitoring apparatus as claimed in claim 11.
